(19) United States
(12) Patent Application Publication
(10) Pub. No.: US 2026/0064593 A1
(43) Pub. Date: Mar. 5, 2026

(54) MEMORY, MEMORY MODULE, AND SEMICONDUCTOR SYSTEM

(71) Applicant: SK hynix Inc., Gyeonggi-do (KR)

(72) Inventors: Min Su PARK, Gyeonggi-do (KR); Kyung Whan KIM, Gyeonggi-do (KR); Choung Ki SONG, Gyeonggi-do (KR)

(21) Appl. No.: 19/010,175

(22) Filed: Jan. 6, 2025

(30) Foreign Application Priority Data
Aug. 28, 2024 (KR) 10-2024-0115986

(51) Int. Cl. G06F 12/06; G06F 11/07; G06F 11/30

(52) U.S. Cl. CPC G06F 12/0692; G06F 11/073; G06F 11/3058

(57) ABSTRACT

A semiconductor system may include a command address bus, a data bus, a management bus, a memory module including multiple memories and coupled to the command address bus, data bus and management bus, a memory controller configured to control, through the command address bus and the data bus, the memory module to perform a write operation and a read operation and a baseboard management controller configured to perform, through the management bus, a management operation of managing the multiple memories.

### CROSS-REFERENCE TO RELATED APPLICATION

This application claims priority under 35 U.S.C. § 119(a) to Korean Patent Application No. 10-2024-0115986, filed on Aug. 28, 2024, the entire contents of which are incorporated herein by reference.

### BACKGROUND

### 1. Technical Field

Embodiments of the present disclosure relate to an integrated circuit technology and, more particularly, to memory, a memory module, and a semiconductor system.

### 2. Related Art

A memory module communicates with a controller. The memory module is controlled based on an instruction that is received from the controller through communication. Accordingly, communication between the memory module and the controller is used for the controller to indicate operations of the memory module because the memory module performs an operation according to the instruction.

Accordingly, for the controller to monitor the state of the memory module, the controller needs to stop the indication of an operation of the memory module and perform communication to identify the state of the memory module. This may cause performance of the memory module to deteriorate.

### SUMMARY

In an embodiment of the present disclosure, a semiconductor system may include a command address bus, a data bus, a management bus, a memory module including multiple memories and coupled to the command address bus, data bus and management bus, a memory controller configured to control, through the command address bus and the data bus, the memory module to perform a write operation and a read operation and a baseboard management controller configured to perform, through the management bus, a management operation of managing the multiple memories.

In an embodiment of the present disclosure, an operating method of a semiconductor system including a controller and multiple memories coupled to the controller through in-band interface and a baseboard management controller coupled to the multiple memories through side-band interfaces, the operating method comprising controlling, by the controller, the multiple memories through the in-band interface, selecting, by the baseboard management controller, one of the multiple memories through the side band interface, receiving, by the baseboard management controller, information from a register of the selected memory and requesting, by the baseboard management controller to the selected memory, a processing operation for fail information when the information includes the fail information.

In an embodiment of the present disclosure, a memory may include a memory cell array configured to perform a read operation or a write operation based on a clock, a command, and an address that are provided through a command/address bus and data that is provided through a data bus, an error correction circuit configured to correct an error of data output as a result of the read operation of reading the data from a memory area within the memory cell array and to store therein a fail address indicating the memory area at which the error has occurred and an alert address processing circuit configured to store therein, when the provided address is identical with the fail address, information provided from the error correction circuit, for determining an error rate of the data.

In an embodiment of the present disclosure, an operating method of a semiconductor system, the operating method comprising, performing, through an in-band interface, a read operation of reading data from a memory area, transmitting, through a side-band interface, information of a fail address indicating the memory area, at which an ECC error has occurred in the data, determining an error rate based on the information and registering the fail address as an alert address when the error rate is greater than a preset error rate.

In an embodiment of the present disclosure, a memory may include a temperature sensor configured to sense a temperature of the memory, a temperature register configured to store therein alert temperature information, and an alert temperature information generation circuit configured to store the alert temperature information in the temperature register when the temperature is greater than a preset range.

### BRIEF DESCRIPTION OF THE DRAWINGS

FIG. 1 is a diagram illustrating a configuration of a semiconductor system according to an embodiment of the present disclosure.

FIG. 2 is a diagram illustrating a configuration of a memory module according to an embodiment of the present disclosure.

FIG. 3 is a diagram illustrating a configuration of memory according to an embodiment of the present disclosure.

FIGS. 4 and 5 are flowcharts for describing operations of the semiconductor system according to an embodiment of the present disclosure.

FIGS. 6 and 7 are diagrams illustrating a configuration of memory according to another embodiment of the present disclosure.

FIGS. 8 and 9 are flowcharts for describing operations of the semiconductor system according to another embodiment of the present disclosure.

FIG. 10 is a diagram illustrating a configuration of memory according to still another embodiment of the present disclosure.

FIG. 11 is a diagram illustrating an operation of the semiconductor system according to still another embodiment of the present disclosure.

### DETAILED DESCRIPTION

Hereinafter, embodiments according to the technical spirit of the present disclosure are described with reference to the accompanying drawings.

Embodiments of the present disclosure provide a memory, a memory module, and a semiconductor system which can prevent the deterioration of performance and monitor the state of the memory module.

A proper operation can be performed based on the state of the memory module because the state of the memory module can be monitored while preventing the deterioration of performance of the memory module and the semiconductor system. Accordingly, it is possible to improve the reliability and performance of the memory, the memory module, and the semiconductor system.

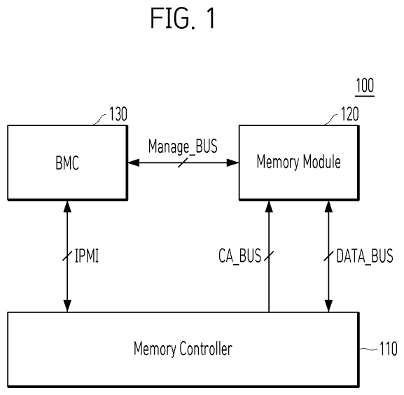

FIG. 1 is a diagram illustrating a configuration of a semiconductor system according to an embodiment of the present disclosure.

Referring to FIG. 1, a semiconductor system 100 according to an embodiment of the present disclosure may include a memory controller 110, a memory module 120, and a baseboard management controller (BMC) 130. In this case, the memory module 120 may include multiple memories (e.g., multiple DRAMs).

The memory controller 110 may control an operation of the memory module 120. The memory controller 110 may be included in a processor, such as a central processing unit (CPU), a graphic processing unit (GPU), or an application processor (AP). The memory controller 110 may transmit a command and an address to the memory module 120 through a command address bus CA_BUS, and may transmit and receive data to and from the memory module 120 through a data bus DATA_BUS.

The memory module 120 may perform a set operation under the control of the memory controller 110. For example, the memory module 120 may perform a read operation, a write operation, etc. under the control of the memory controller 110. The memory module 120 may perform an operation that is indicated by a command and an address that are received through the command address bus CA_BUS, may transmit data to the memory controller 110 through the data bus DATA_BUS after the start of the read operation, and may receive data that are received through the data bus DATA_BUS after the start of a write operation. That is, the memory module 120 may distinguish between a read operation and a write operation based on a command and an address that are received through the command address bus CA_BUS, may transmit data that are stored in the memory module 120 to the memory controller 110 through the data bus DATA_BUS after the start of a read operation, and may store the data that are received through the data bus DATA_BUS after the start of the read operation.

The BMC 130 may be configured to perform a management and monitoring function that is mounted on a basic board of a device, such as a server or a PC. The BMC 130 may communicate with the memory module 120 and manage circuits within the memory module 120. Furthermore, the BMC 130 may also communicate with the memory controller 110, may identify the state of the semiconductor system, and may manage the semiconductor system or diagnoses a problem. For example, the BMC 130 may manage multiple memories (e.g., multiple DRAMs) within the memory module. An interface called an intelligent platform management interface (IPMI) may be basically used for communication between the BMC 130 and the memory controller 110. Furthermore, communication between the BMC 130 and the memory module 120 may be performed through a management bus Manage_BUS. A memory module management control (M3C) interface that is similar to an inter-integrated circuit (I2C) interface may be used as the management bus Manage_BUS.

The command address bus CA_BUS and the data bus DATA_BUS between the memory controller 110 and the memory module 120 are each a bus that is used to perform a main function of the memory module 120, and thus such an interface is called an in-band interface. In this case, an external chip selection signal, an external clock, an external address ADDR, an external command CMD, and data DQ may be transmitted and received through the in-band interface. Specifically, the external chip selection signal CS_e, the external address ADDR, the external command CMD, and the external clock CLK_e may be transmitted and received through the command address bus CA_BUS, and the data DQ may be transmitted and received through the data bus DATA_BUS. Furthermore, the management bus Manage_BUS between the BMC 130 and the memory module 120 is a bus that is used for the additional control or management of the memory module 120, and thus such an interface is called a side-band interface. In this case, a management clock and a management control signal may be transmitted and received through the side-band interface, that is, the management bus Manage_BUS.

The semiconductor system 100 constructed as described above according to an embodiment of the present disclosure may perform the following operations.

While the memory controller 110 controls the memory module 120, the BMC 130 may monitor the state of the memory module 120, may determine the results of the monitoring, and may transmit the results of the determination to the memory controller 110 or request a proper operation from the memory module 120 based on the results of the determination. For example, when determining that an error has occurred in the monitored state of the memory module 120, the BMC 130 may request an operation for processing the error which occurred in the memory module 120, from the memory module 120.

More specifically, the memory controller 110 may communicate with the memory module 120 through the in-band interface. In this case, the in-band interface may include the command address bus CA_BUS and the data bus DATA_BUS. The command address bus CA_BUS may be a bus to and from which the external chip selection signal CS_e, the external address ADDR, the external command CMD, and the external clock CLK_e are transmitted and received, and may be a bus to and from which the data DQ are transmitted and received through the data bus DATA_BUS. As described above, the memory controller 110 may select one of multiple memories within the memory module 120 by using the external chip selection signal CS_e, and may enable a main operation of the selected memory to be performed by providing the selected memory with the command CMD and the address ADDR. For example, the main operation of the memory may include a write operation of storing data and a read operation of outputting data stored in the memory. The selected memory may distinguish between a write operation and a read operation based on the command CMD, and may determine a location at which data will be stored or the location of data stored in the selected memory, based on the address ADDR. Furthermore, the selected memory may be provided with data to be stored in the selected memory through the data bus DATA_BUS after the start of a write operation, and may output data stored in the selected memory through the data bus DATA_BUS after the start of a read operation.

As described above, while the memory controller 110 performs a main operation (e.g., a read operation or a write operation) of the memory module 120 through the in-band interface, the BMC 130 may monitor the state of the memory module 120 through the management bus Manage_BUS and determine the results of the monitoring. Furthermore, in a situation in which the memory controller 110 cannot control an operation of the memory module 120, for example, in a situation prior to the power-up of the memory controller 110, the BMC 130 may monitor the state of the memory module 120 and determine the results of the monitoring. Furthermore, the BMC 130 may transmit the results of the determination to the memory controller 100 through the intelligent platform management interface (IPMI). The memory controller 100 may determine whether an error occurred in the memory module 120 based on the received information, and may control a processing operation for the error which occurred in the memory module 120, to be performed. The BMC 130 may determine the results of the monitoring, and may control the memory module 120 to perform a processing operation on an error when the error occurs in the memory module 120 based on the results of the determination.

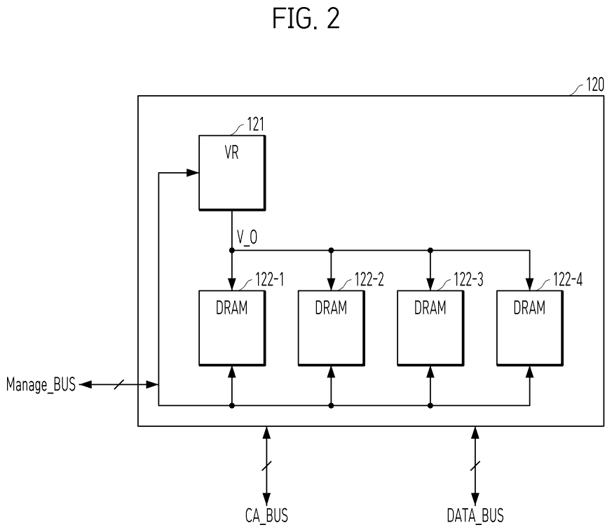

The embodiments of operations of the semiconductor system 100 are described more specifically as follows with reference to FIGS. 2 to 11. Embodiments described with reference to FIGS. 2 to 11 are merely embodiments, and the present disclosure is not limited to the embodiments.

A configuration of the memory module 120 that is included in the semiconductor system 100 according to an embodiment of the present disclosure is described as follows with reference to FIG. 2.

FIG. 2 is a diagram illustrating a configuration of the memory module according to an embodiment of the present disclosure. In this case, the memory module 120 may include multiple memories 122-1, 122-2, 122-3, and 122-4.

Referring to FIG. 2, the memory module 120 may include a voltage generation circuit (VR) 121 and the multiple memories 122-1, 122-2, 122-3, and 122-4. In this case, the multiple memories 122-1, 122-2, 122-3, and 122-4 may each include DRAM.

The voltage generation circuit 121 may provide a source voltage V_O to each of the multiple memories 122-1, 122-2, 122-3, and 122-4. For example, the voltage generation circuit 121 may control the level of the source voltage V_O through the management bus Manage_BUS, that is, the side-band interface. The voltage generation circuit 121 may control the level of the source voltage V_O through the in-band interface, that is, at least one bus of the command address bus CA_BUS and the data bus DATA_BUS, although not illustrated. In this case, the level of the source voltage V_O may be controlled to be higher or lower than a target level, and the level of the source voltage V_O, which is lower or higher than the target level, may be controlled to return to the target level.

Each of the multiple memories 122-1, 122-2, 122-3, and 122-4 may transmit and receive the external chip selection signal CS_e, the external address ADDR, the external command CMD, the external clock CLK_e, and the data DQ to and from the memory controller 110 through the command address bus CA_BUS and the data bus DATA_BUS. For example, each of the multiple memories 122-1, 122-2, 122-3, and 122-4 may receive the external chip selection signal CS_e, the external address ADDR, the external command CMD, and the external clock CLK_e through the command address bus CA_BUS, and may transmit and receive the data DQ through the data bus DATA_BUS.

Furthermore, each of the multiple memories 122-1, 122-2, 122-3, and 122-4 may transmit and receive the management clock SCL and the management control signal SCA to and from the BMC 130 through the management bus Manage_BUS. For example, each of the multiple memories 122-1, 122-2, 122-3, and 122-4 may include a register (not illustrated). The register may store the state information of the memory. The register of each of the multiple memories 122-1, 122-2, 122-3, and 122-4 may provide the state information to the BMC 130 through the management bus Manage_BUS. In this case, the state information of the memory may include pieces of temperature information, error information, and word line information.

As a result, each of the multiple memories 122-1, 122-2, 122-3, and 122-4 according to an embodiment of the present disclosure may transmit the state information of each of the multiple memories to the BMC 130 through the side-band interface, while performing a main operation, such as a read operation or a write operation, through the in-band interface along with the memory controller 110.

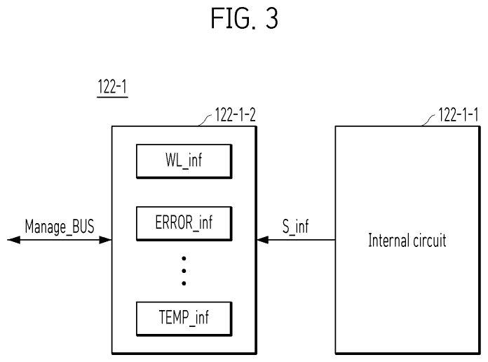

FIG. 3 is a diagram illustrating a configuration of memory according to an embodiment of the present disclosure. In this case, the configuration of the memory illustrated in FIG. 3 may be a configuration of each of the multiple memories illustrated in FIG. 2. FIG. 3 illustrates a configuration of the memory 122-1, which represents the configuration of each of the multiple memories 122-1, 122-2, 122-3, and 122-1.

Referring to FIG. 3, the memory 122-1 may include an internal circuit 122-1-1 and a register 122-1-2.

The internal circuit 122-1-1 may be a circuit that senses the state of the memory. For example, the internal circuit 122-1-1 may be a circuit constructed to sense a word line that is accessed a preset number of times or more. Furthermore, the internal circuit 122-1-1 may be a circuit constructed to sense error information. In an embodiment, the internal circuit 122-1-1 may be a circuit constructed to sense ECC error information. Furthermore, the internal circuit 122-1-1 may be a circuit constructed to sense temperature information. In an embodiment, the internal circuit 122-1-1 may be a temperature sensor. Furthermore, the internal circuit 122-1-1 may be constructed to sense whether a word line that is accessed a preset number of times or more is present, whether an error that has occurred more than at a preset error rate is present, or a temperature state in which a temperature is a preset temperature or more.

As described above, the internal circuit 122-1-1 may be constructed to sense the state of the memory, which is greater than a preset range, and may transmit a sensing result S_inf to the register 122-1-2.

The register 122-1-2 may store the sensing result S_inf, and may transmit the stored sensing result to the BMC 130 through the management bus Manage_BUS. For example, the register 122-1-2 may receive at least one of word line information WL_inf, error information ERROR_inf, and the temperature information TEMP_inf from the internal circuit 122-1-1, may store the received information, and may transmit the stored information to the BMC 130 through the management bus Manage_BUS. In an embodiment, the BMC 130 may monitor the state information that is stored in the register of each of the multiple memories 122-1, 122-2, 122-3, and 122-4 through the management bus Manage_BUS. In this case, the state information may include at least one of the word line information WL_inf, the error information ERROR_inf, and the temperature information TEMP_inf. In an embodiment, when the word line information WL_inf stored in the register 122-1-2 is a high level, this may mean that a word line that has been accessed a preset number of times or more is present. When the word line information WL_inf stored in the register 122-1-2 is a low level, this may mean that a word line that has been accessed a preset number of times or more is not present. Furthermore, when the error information ERROR_inf stored in the register 122-1-2 is a high level, this may mean that an error that has occurred more than at a preset error rate is present. When the error information ERROR_inf stored in the register 122-1-2 is a low level, this may mean that an error that has occurred more than at a preset error rate is not present. Furthermore, when the temperature information TEMP_inf stored in the register 122-1-2 is a high level, this may mean that the temperature of the memory is greater than a preset temperature range. When the temperature information TEMP_inf stored in the register 122-1-2 is a low level, this may mean that the temperature of the memory is within a preset temperature range.

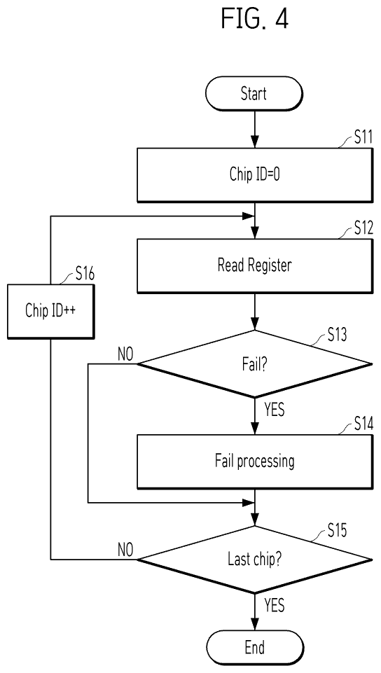

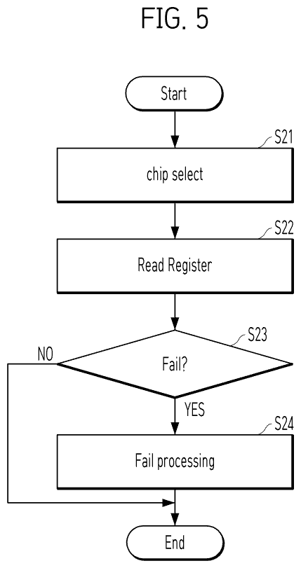

FIGS. 4 and 5 are flowcharts for describing operations of the semiconductor system according to an embodiment of the present disclosure. In particular, FIGS. 4 and 5 are flowcharts for describing operations of the BMC 130 monitoring the multiple memories 122-1, 122-2, 122-3, and 122-4.

FIG. 4 is a flowchart that describes an operation of the BMC 130 periodically monitoring the state of each of the multiple memories 122-1, 122-2, 122-3, and 122-4.

Referring to FIG. 4, an operating method of the semiconductor system may include a first memory selection process S11, a register storage information reading process S12, a storage information determination process S13, a processing process S14, a last memory confirmation process S15, and a next memory selection process S16.

The first memory selection process S11 may include a process of selecting the first memory, among the multiple memories 122-1, 122-2, 122-3, and 122-4. In this case, the multiple memories 122-1, 122-2, 122-3, and 122-4 may include the first memory 122-1, the second memory 122-2, the third memory 122-3, and the fourth memory 122-4. Furthermore, the first memory 122-1 may be memory having a chip ID of 0. The second memory 122-2 may be memory having a chip ID of 1. The third memory 122-3 may be memory having a chip ID of 2. The fourth memory 122-4 may be memory having a chip ID of 3. Accordingly, the first memory selection process S11 may be a process of selecting, by the BMC 130, the memory having the chip ID of 0, among the multiple memories 122-1, 122-2, 122-3, and 122-4.

The register storage information reading process S12 may include a process of reading storage information from the register of the selected memory. For example, the register storage information reading process S12 may include a process of reading, by the BMC 130, information stored in the register of the selected memory through the management bus Manage_BUS.

The storage information determination process S13 may include a process of determining the read storage information of the register. For example, the storage information determination process S13 may include a process of determining whether the read storage information of the register includes fail information. In this case, the register may store the state information of the selected memory, which is greater than a preset range. In an embodiment, when a word line that has been accessed a preset number of times or more is present, the word line information WL_inf stored in the register 122-1-2 may have a value of a high level. When an error that has occurred more than a preset error rate is present, the error information ERROR_inf stored in the register 122-1-2 may have a value of a high level. When a temperature of the selected memory is greater than a preset temperature range, the temperature information TEMP_inf stored in the register 122-1-2 may have a value of a high level. As described above, the storage information determination process S13 may include a process of determining whether the read storage information of the register includes fail information, that is, whether the read storage information has a value of a high level. Accordingly, the storage information determination process S13 may include a process of determining, by the BMC 130, whether the read storage information of the register includes fail information, that is, whether the read storage information has a value of a high level, through the management bus Manage_BUS. It has been described that the fail information is the read storage information having a value of a high level, but the fail information may be the read storage information having a value of a low level depending on a setting situation. The present disclosure is not limited to a case in which the fail information is the read storage information having a value of a high level.

When the fail information is checked (YES) in the storage information determination process S13, the processing process S14 may be performed. If the fail information is not checked (NO) in the storage information determination process S13, the last memory confirmation process S15 may be performed.

The processing process S14 is a process that is performed when the fail information is checked, and may include a process of transmitting the fail information to the memory controller 110. For example, when the word line information WL_inf includes the fail information, the processing process S14 may include transmitting, to the memory controller 110 through the IPMI, information indicating that a word line that has been accessed a preset number of times or more is present. The processing process S14 may include transmitting, to the memory controller 110 through the IPMI when the error information ERROR_inf includes the fail information, information indicating that an error has occurred more than a preset error rate. The processing process S14 may include transmitting, to the memory controller 110 through the IPMI when the temperature information TEMP_inf includes the fail information, information indicating that a temperature of the selected memory is greater than a preset temperature range.

The processing process S14 may include a process of instructing the selected memory to perform a processing operation according to the fail information. The processing process S14 may include transmitting, by the BMC 130 to the voltage generation circuit 121 when the temperature information TEMP_inf of the selected memory includes the fail information, an instruction to lower the level of the source voltage V_O that is provided to each of the multiple memories 122-1, 122-2, 122-3, and 122-4 through the side-band interface, that is, the management bus Manage_BUS.

The last memory confirmation process S15 may include a process of selecting the last memory, among the multiple memories 122-1, 122-2, 122-3, and 122-4. As described above, the first memory 122-1 may have the chip ID of 0. The second memory 122-2 may have the chip ID of 1. The third memory 122-3 may have the chip ID of 2. The fourth memory 122-4 may have the chip ID of 3. In this case, the last memory confirmation process S15 may be a process of confirming that the chip ID of the last memory including the register storage information of which has been read in the register storage information reading process S12 is 3. That is, the last memory confirmation process S15 may include a process of determining, by the BMC 130, whether storage information of the register of memory having the greatest chip ID value, among the multiple memories 122-1, 122-2, 122-3, and 122-4, has been read.

When the selected memory is memory having a chip ID in which the read information of the register has the greatest value (YES) in the last memory confirmation process S15, the operating method of the semiconductor system according to an embodiment of the present disclosure may be terminated.

When the selected memory is not memory having a chip ID in which the read information of the register has the greatest value (NO) in the last memory confirmation process S15, the next memory selection process S16 may be performed.

The next memory selection process S16 is a process that is performed when the read storage information of the register is not the memory having the greatest chip ID value (NO), and may include a process of selecting memory next to the memory having the read storage information of the register. In an embodiment, the next memory selection process S16 may be a process of selecting memory having a chip ID that is one step higher than the chip ID of memory having read storage information of the register. For example, the next memory selection process S16 may include a process of selecting the memory having the chip ID of 1, when the chip ID of memory including a register storage information of which has been read in the register storage information reading process S12 is 0. The next memory selection process S16 may include a process of selecting the memory having the chip ID of 2, when the chip ID of memory including a register storage information of which has been read in the register storage information reading process S12 is 1. The next memory selection process S16 may include a process of selecting the memory having the chip ID of 3, when the chip ID of memory including a register storage information of which has been read in the register storage information reading process S12 is 2.

As described above, the operating method of the semiconductor system according to an embodiment of the present disclosure may be a method of monitoring the state of each of the multiple memories in order according to a chip ID. The operating method of the semiconductor system may be periodically performed.

FIG. 5 is a flowchart illustrating an operating method of the semiconductor system in which the BMC 130 selects one of the multiple memories 122-1, 122-2, 122-3, and 122-4 and monitors the state of the selected memory.

Referring to FIG. 5, the operating method of the semiconductor system may include a chip selection process S21, a register storage information reading process S22, a storage information determination process S23, and a processing process S24.

The chip selection process S21 may include a process of selecting one of the multiple memories 122-1, 122-2, 122-3, and 122-4. For example, the chip selection process S21 may include a process of selecting, by the BMC 130, one of the multiple memories 122-1, 122-2, 122-3, and 122-4 through the management bus Manage_BUS.

The register storage information reading process S22 may include a process of reading storage information from a register that is included in the selected memory. For example, the register storage information reading process S22 may include a process of reading, by the BMC 130, the storage information of the register of the selected memory through the management bus Manage_BUS.

The storage information determination process S23 may include a process of determining whether the read storage information of the register includes fail information. In this case, the fail information may be the state information stored in the register and may represent a status value greater than a preset range as described above with reference to FIG. 4. The storage information determination process S23 may include a process of subsequently checking whether the storage information of the register of the selected memory, which has been read in the register storage information reading process S22, has been stored as the fail information.

When the fail information is checked (YES) in the storage information determination process S23, the processing process S24 may be performed. When the fail information is not checked (NO) in the storage information determination process S23, the operating method of the semiconductor system according to an embodiment of the present disclosure may be terminated.

The processing process S24 is a process that is performed when the fail information is checked, and may include a process of transmitting the fail information to the memory controller 110. For example, the processing process S24 may include transmitting, to the memory controller 110 through the IPMI when the word line information WL_inf includes the fail information, information indicating that a word line that has been accessed a preset number of times or more is present. The processing process S24 may include transmitting, to the memory controller 110 through the IPMI when the error information ERROR_inf includes the fail information, information, indicating that an error has occurred more than a preset error rate. The processing process S24 may include transmitting to the memory controller 110 through the IPMI when the temperature information TEMP_inf includes the fail information, information indicating that a temperature of the selected memory is greater than a preset temperature range.

The processing process S24 may include a process of instructing the selected memory to perform a processing operation according to the fail information. The processing process S24 may include transmitting, by the BMC 130 to the voltage generation circuit 121 when the temperature information TEMP_inf of the selected memory includes the fail information, an instruction to lower the level of the source voltage V_O that is provided to each of the multiple memories 122-1, 122-2, 122-3, and 122-4 through the side-band interface, that is, the management bus Manage_BUS.

In the processing process S14 and S24 illustrated in FIGS. 4 and 5, when the fail information according to the state of the selected memory is transmitted to the memory controller 110, the memory controller 110 may operate as follows.

When information indicating that a specific word line has been accessed a preset number of times or more is transmitted to the memory controller 110 as the word line information WL_inf, the memory controller 110 may determine that a row hammering issue has occurred, and may transmit an instruction that enables a refresh operation to be performed on neighbouring word lines adjacent to the word line that has been accessed by the preset number of times or more to memory from which the fail information has been output.

Furthermore, when information indicating that an error has occurred more than at a preset error rate is transmitted to the memory controller 110 as the error information ERROR_inf, the memory controller 110 may treat, as a bad block, a memory block that belongs to the selected memory and that has the error that has occurred more than the preset error rate, and may perform a repair operation.

Furthermore, when the temperature information TEMP_inf indicating that a temperature of the selected memory is greater than a preset temperature range is transmitted to the memory controller 110, the memory controller 110 may provide the voltage generation circuit 121 that provides the source voltage V_O to the multiple memories 122-1, 122-2, 122-3, and 122-4 with an instruction to change the level of the source voltage V_O.

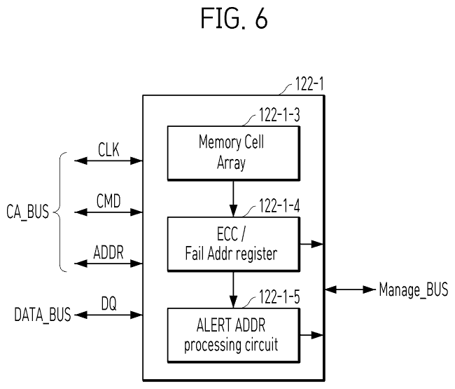

FIGS. 6 to 9 are diagrams that more specifically describe a configuration of memory and an operation of the semiconductor system, when fail information stored in the register of the memory is the error information ERROR_inf.

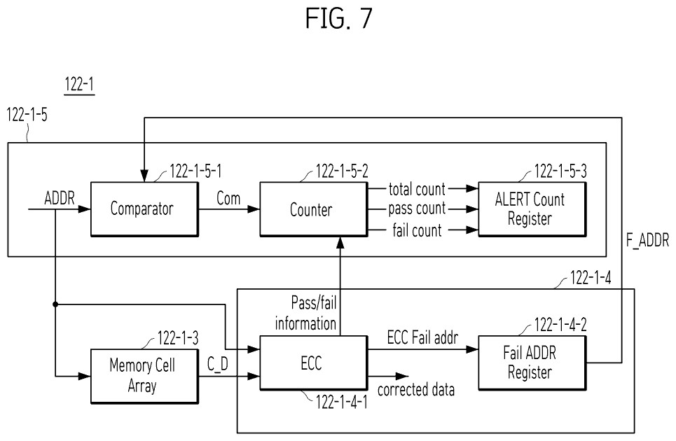

FIGS. 6 and 7 are diagrams illustrating a configuration of memory according to another embodiment of the present disclosure. In this case, the configuration of the memory illustrated in FIG. 6 may be a configuration of each of the multiple memories illustrated in FIG. 2. FIG. 6 illustrates the configuration of the memory 122-1 that represents the configuration of each of the multiple memories 122-1, 122-2, 122-3, and 122-1.

Referring to FIG. 6, the memory 122-1 may receive an external clock CLK, an external command CMD, and an external address ADDR from the memory controller 110 through the command address bus CA_BUS, and may transmit and receive data DQ to and from the memory controller 110 through the data bus DATA_BUS. For example, the memory 122-1 may perform a read operation or a write operation based on the external clock CLK and the external command CMD that are received from the memory controller 110, and may designate a location at which a read operation or a write operation will be performed based on the external address ADDR. In this case, the memory 122-1 may transmit, to the memory controller 110, the data DQ that are output from memory cells at a designated location after the start of a read operation through the data bus DATA_BUS. The memory 122-1 may store the data DQ that are received from the memory controller 110 through the data bus DATA_BUS in memory cells at a designated location after the start of a write operation.

The BMC 130 may receive the error information ERROR_inf stored in the memory 122-1 through the management bus Manage_BUS.

The memory 122-1 that operates as described above may include a memory cell array 122-1-3, an error correction circuit (ECC/Fail Addr register) 122-1-4, and an alert address (ALERT ADDR) processing circuit 122-1-5.

The memory cell array 122-1-3 may include a plurality of memory cells that store the data DQ. Furthermore, the memory cell array 122-1-3 may additionally include a plurality of word lines and a plurality of bit lines. The plurality of memory cells may be connected to the plurality of word lines and the plurality of bit lines. Furthermore, some of the plurality of memory cells may be designated by at least one word line selected from among the plurality of word lines and at least one bit line selected from among the plurality of bit lines. A read operation may be an operation of outputting data that are stored in a designated memory cell. A write operation may be an operation of storing data in a designated memory cell.

The error correction circuit 122-1-4 may correct an error of the data DQ that are output after the start of a read operation, and may store the address of memory cells that have stored the data DQ having an error which occurred as an ECC fail address ECC Fail addr. The error correction circuit 122-1-4 may include an ECC circuit that corrects an error of the data DQ after the start of a read operation and a fail address (Fail Addr) register that stores the ECC fail address ECC Fail addr.

The alert address processing circuit 122-1-5 may store information on which an error rate of the data DQ that are output from memory cells designated by the external address ADDR when the received external address ADDR is identical with the ECC fail address ECC Fail addr after the start of a read operation, may be determined. In this case, the alert address processing circuit 122-1-5 may include a register that enables the BMC 130 to receive information on which the error rate may be determined through the management bus Manage_BUS.

The configuration of the memory 122-1 is described more specifically as follows with reference to FIG. 7.

The error correction circuit 122-1-4 may include an ECC circuit (ECC) 122-1-4-1 and a fail address register (Fail ADDR Register) 122-1-4-2.

The ECC circuit 122-1-4-1 may correct an error of cell data C_D that are output by the memory cell array 122-1-3 after the start of a read operation, and may output the corrected data. In this case, when correcting the error, the ECC circuit 122-1-4-1 may transmit the external address ADDR that is received after the start of the read operation to the fail address register 122-1-4-2 as the ECC fail address ECC Fail addr. Furthermore, the ECC circuit 122-1-4-1 may provide the alert address processing circuit 122-1-5 with pass/fail information of the cell data C_D for the external address ADDR that is received after the start of the read operation. In this case, the pass/fail information of the cell data C_D may mean whether error correction for the cell data C_D is present. For example, the pass information of the cell data C_D may mean that error correction for the cell data C_D is not present. The fail information of the cell data C_D may mean that error correction for the cell data C_D is present.

The fail address register 122-1-4-2 may store the ECC fail address ECC Fail addr that is received from the error correction circuit 122-1-4, and may provide the alert address processing circuit 122-1-5 with the ECC fail address ECC Fail addr stored in the fail address register 122-1-4-2 as a fail address F_ADDR. Furthermore, the fail address register 122-1-4-2 may also provide the fail address F_ADDR to the BMC 130 through the management bus Manage_BUS.

The alert address processing circuit 122-1-5 may include a comparator 122-1-5-1, a counter 122-1-5-2, and an alert count register 122-1-5-3.

The comparator 122-1-5-1 may compare the fail address F_ADDR and the external address ADDR that is received through the command address bus CA_BUS. In this case, when the fail address F_ADDR and the external address ADDR are identical with each other, the comparator 122-1-5-1 may output a comparison result signal Com that operates the counter 122-1-5-2.

The counter 122-1-5-2 may operate when the fail address F_ADDR and the external address ADDR are identical with each other. The counter 122-1-5-2 may count the pass/fail information that is provided by the ECC circuit 122-1-4-1. In this case, the counter 122-1-5-2 may increase a pass count value whenever the pass information is received. The counter 122-5-2 may increase a fail count value whenever the fail information is received. The counter 122-1-5-2 may increase a total count value whenever any of the pass information and the fail information is received.

The alert count register 122-1-5-3 may store values that are counted by the counter 122-1-5-2, that is, the pass count value, fail count value, and total count value of each fail address F_ADDR. The count values stored in the alert count register 122-1-5-3 may be transmitted to the BMC 130 through the management bus Manage_BUS.

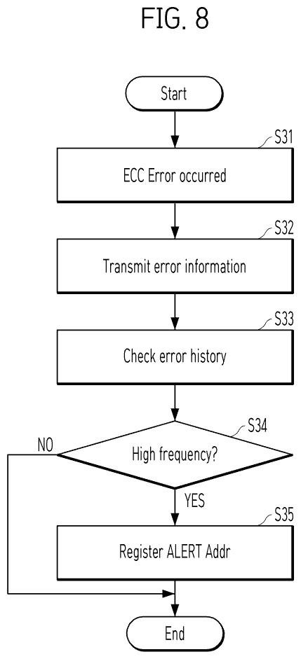

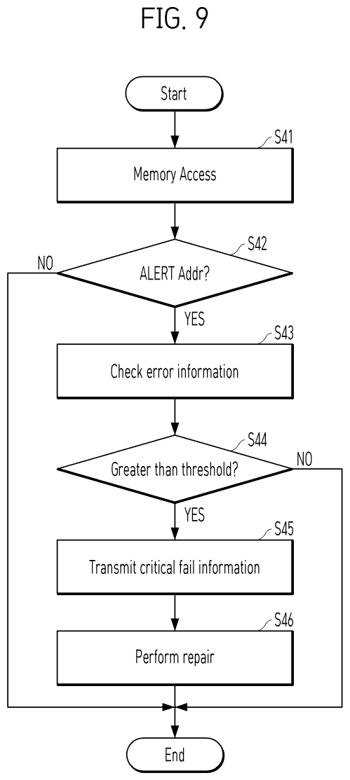

FIGS. 8 and 9 are flowcharts for describing operations of the semiconductor system according to another embodiment of the present disclosure.

FIG. 8 is a flowchart for describing an operation method of the semiconductor system, which is performed prior to an operation of the semiconductor system in FIG. 9. In particular, FIG. 8 is a flowchart for describing an operation method of registering an alert address in the operation of the semiconductor system.

Referring to FIG. 8, the operating method of the semiconductor system according to another embodiment of the present disclosure may include an error sensing process S31, an error information transmission process S32, an error history check process S33, an alert address determination process S34, and an alert address registration process S35.

The error sensing process S31 may include a process of sensing an error occurred in data that are output by the memory cell array 122-1-3 after the start of a read operation. For example, the error sensing process S31 is a process that is performed by the ECC circuit 122-1-4-1 and may include a process of correcting and outputting, by the ECC circuit 122-1-4-1, data that are output by the memory cell array 122-1-3. In this case, the error sensing process S31 may further include a process of storing, as the fail address F_ADDR, the external address ADDR that is received after the start of a read operation.

The error information transmission process S32 may include a process of transmitting, to the BMC 130, a pass count value, fail count value, and total count value of the fail address F_ADDR stored in the alert count register 122-1-5-3 through the management bus Manage_BUS.

The error history check process S33 may include a process of checking the error history of the fail address F_ADDR, based on the pass count value, fail count value, and total count value of the fail address F_ADDR. For example, the error history check process S33 may include a process of analyzing, by the BMC 130, the pass count value, fail count value, and total count value of the fail address F_ADDR, which are received through the management bus Manage_BUS.

The alert address determination process S34 may include a process of comparing an error occurrence ratio of the fail address F_ADDR with a preset ratio. In this case, the error occurrence ratio may mean a fail count value for a pass count value or a fail count value for a total count value.

When the error occurrence ratio of the fail address F_ADDR is higher than the preset ratio in the alert address determination process S34, the BMC 130 may determine that an error occurs in the fail address F_ADDR with high frequency. When the error occurrence ratio of the fail address F_ADDR is lower than the preset ratio in the alert address determination process S23, the BMC 130 may determine that an error occurs in the fail address F_ADDR with low frequency.

Accordingly, when the error occurrence ratio of the fail address F_ADDR is higher than the preset ratio (YES) in the alert address determination process S34, the BMC 130 may determine that an error occurs in the fail address F_ADDR with high frequency, and the alert address registration process S35 of registering the fail address F_ADDR as an alert address ALERT Addr may be performed.

When the error occurrence ratio of the fail address F_ADDR is lower than the preset ratio (NO) in the alert address determination process S23, the BMC 130 determines that an error occurs in the fail address F_ADDR with low frequency, and the operating method of the semiconductor system according to another embodiment of the present disclosure may be terminated.

FIG. 9 is a flowchart for describing an operation of the semiconductor system after the fail address F_ADDR is registered as the alert address ALERT Addr in FIG. 8.

Referring to FIG. 9, the operating method of the semiconductor system according to another embodiment of the present disclosure may include a memory access process S41, an alert address check process S42, a cumulative error information check process S43, a cumulative error determination process S44, a critical fail information transmission process S45, and a repair process S46.

The memory access process S41 may include a process of performing a read operation on memory. In this case, in the memory access process S41, after the start of the read operation, the external address ADDR may be input to the memory. The external address ADDR may be a signal to designate a data storage region of the memory on which the read operation is performed.

The alert address check process S42 may include a process of comparing the external address ADDR that is received after the start of the read operation and the alert address ALERT Addr.

When the external address ADDR is identical with the alert address ALERT Addr (YES) in the alert address check process S42, the cumulative error information check process S43 may be performed.

When the external address ADDR is not identical with the alert address ALERT Addr in the alert address check process S42 (NO), the operating method of the semiconductor system according to another embodiment of the present disclosure may be terminated.

The cumulative error information check process S43 is a process that is performed when the external address ADDR received after the start of the read operation is identical with the alert address ALERT Addr, and may include a process of checking count values stored in the alert count register 122-1-5-3. In this case, the cumulative error information check process S43 may include a process of receiving, by the BMC 130, the count values (e.g., a pass count value, a fail count value, and a total count value) stored in the alert count register 122-1-5-3 through the management bus Manage_BUS.

The cumulative error determination process S44 may include a process of determining whether at least one of the pass count value, fail count value, and total count value of the fail address F_ADDR registered as the alert address ALERT Addr is greater than a set value. That is, the cumulative error determination process S44 may include a process of determining whether at least one of the pass count value, fail count value, and total count value of the alert address ALERT Addr is greater than a threshold. In this case, the cumulative error determination process S44 may be a process that is performed by the BMC 130 that receives the count values stored in the alert count register 122-1-5-3.

When at least one of the count values of the alert address ALERT Addr is greater than the threshold (YES) in the cumulative error determination process S44, the critical fail information transmission process S45 may be performed.

When at least one of the count values of the alert address ALERT Addr is not greater than the threshold (NO) in the cumulative error determination process S44, the operating method of the semiconductor system according to another embodiment of the present disclosure may be terminated.

The critical fail information transmission process S45 may include a process of transmitting information indicating that a critical error has occurred in the data storage region of the memory cell array 122-1-3, which is designated by the alert address ALERT Addr. In this case, the BMC 130 may transmit the information, indicating that the critical error has occurred in the data storage region designated by the alert address ALERT Addr, to the memory module 120 through the management bus Manage_BUS. Alternatively, the BMC 130 may transmit the information, indicating that the critical error has occurred in the data storage region designated by the alert address ALERT Addr, to the memory controller 110 through the IPMI.

The repair process S46 may include performing a repair operation of substituting the data storage region in which the critical error has occurred with another data storage region. In this case, a process of processing the data storage region in which the critical error has occurred as a bad block may be further performed. For example, the repair process S45 may be an operation that is performed within the memory module 120, and may be an operation that is indicated in the memory module 120 and performed by the memory controller 110.

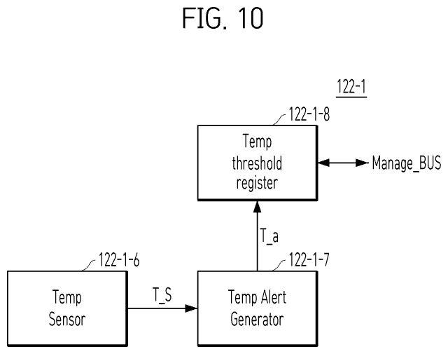

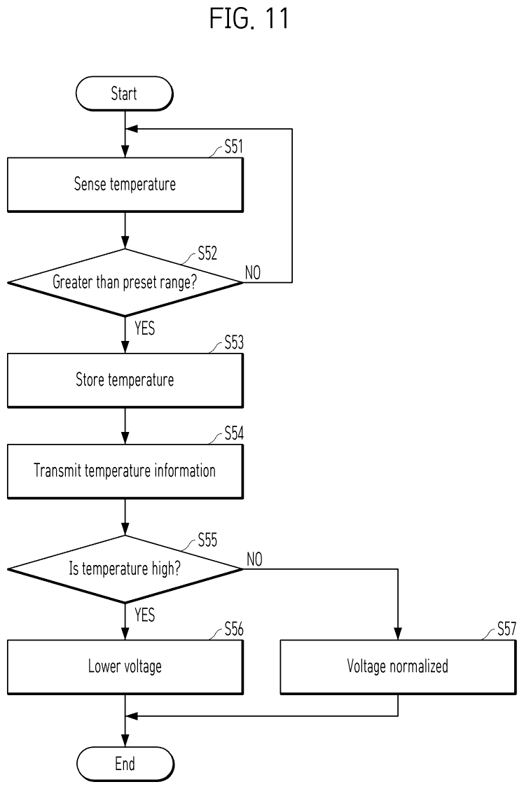

FIGS. 10 and 11 are diagrams for more specifically describing a configuration of the memory and an operation of the semiconductor system when the temperature information TEMP_inf stored in the register includes the fail information.

FIG. 10 is a diagram illustrating a configuration of memory according to still another embodiment of the present disclosure. In this case, the configuration of the memory illustrated in FIG. 10 may be a configuration of each of the multiple memories illustrated in FIG. 2. FIG. 10 illustrates the configuration of the memory 122-1 that represents the configuration of each of the multiple memories 122-1, 122-2, 122-3, and 122-1.

Referring to FIG. 10, the memory 122-1 may include a temperature sensor (Temp Sensor) 122-1-6, an alert temperature information generation circuit (Temp Alert Generator) 122-1-7, and a temperature register (Temp threshold register) 122-1-8.

The temperature sensor 122-1-6 may sense a temperature of the memory 122-1, and may transmit the sensed temperature to the alert temperature information generation circuit 122-1-7 as temperature information T_s.

The alert temperature information generation circuit 122-1-7 may compare the temperature information T_s and a preset temperature range. When the temperature information T_s is greater than the preset temperature range, the alert temperature information generation circuit 122-1-7 may transmit, to the temperature register 122-1-8, the temperature information T_s that is received from the temperature sensor 122-1-6 as alert temperature information T_a.

The temperature register 122-1-8 may store the alert temperature information T_a that is received from the alert temperature information generation circuit 122-7. Furthermore, the alert temperature information T_a that is stored in the temperature register 122-1-8 may be transmitted to the BMC 130 through the management bus Manage_BUS.

FIG. 11 is a diagram illustrating an operation of the semiconductor system according to still another embodiment of the present disclosure.

Referring to FIG. 11, the operation of the semiconductor system may include a temperature sensing process S51, a first temperature determination process S52, a temperature information storage process S53, a temperature information transmission process S54, a second temperature determination process S55, a first voltage control process S56, and a second voltage control process S57.

The temperature sensing process S51 may include a process of sensing, by the temperature sensor 122-1-6, a temperature of memory.

The first temperature determination process S52 may include a process of determining whether the temperature information T_s that is sensed in the temperature sensing process S51 is greater than a first preset temperature range. The first temperature determination process S52 may be a process that is performed by the alert temperature information generation circuit 122-1-7 included in the memory 122-1.

When the temperature information T_s is greater than the first preset temperature range (YES) in the first temperature determination process S52, for example, when the temperature of the memory 122-1 is greater than the first preset temperature range (YES), the temperature information storage process S53 may be performed.

When the temperature information T_s is within the first preset temperature range (NO) in the first temperature determination process S52, for example, when the temperature of the memory 122-1 is within the first preset temperature range (NO), the temperature sensing process S51 may be performed.

The temperature information storage process S53 may include a process of storing, in the temperature register 122-1-8, the temperature information T_s that is greater than the first preset temperature range in the first temperature determination process S52 as the alert temperature information T_a.

The temperature information transmission process S54 may include a process of transmitting, to the BMC 130, the alert temperature information T_a stored in the temperature register 122-1-8 through the management bus Manage_BUS.

The second temperature determination process S55 is a process that is performed by the BMC 130, and may include a process of determining whether the alert temperature information T_a that is received from the temperature register 122-1-8 of the memory 122-1 is greater than a second preset temperature range.

When the temperature based on the alert temperature information T_a is greater than the second preset temperature range (YES) in the second temperature determination process S55, that is, when it is determined that the temperature of the memory 122-1 is high (YES), the first voltage control process S56 may be performed.

When the temperature based on the alert temperature information T_a is within the second preset temperature range (NO) in the second temperature determination process S55, that is, when it is determined that the temperature of the memory 122-1 is normal (NO), the second voltage control process S57 may be performed.

The first voltage control process S56 may include a process of controlling, by the BMC 130, the level of the source voltage V_O through the voltage generation circuit 121 illustrated in FIG. 2 through the management bus Manage_BUS. In this case, in the first voltage control process S56, an embodiment in which the level of the source voltage V_O is controlled to be lowered has been described.

The second voltage control process S57 may include a process of controlling, by the BMC 130, the level of the source voltage V_O through the voltage generation circuit 121 illustrated in FIG. 2 through the management bus Manage_BUS. In this case, in the second voltage control process S57, an embodiment in which the level of the source voltage V_O that is varied in the first voltage control process S56 is controlled to return to a normal level has been described.

Although embodiments according to the technical spirit of the present disclosure have been described above with reference to the accompanying drawings, the embodiments have been provided to merely describe embodiments according to the concept of the present disclosure, and the present disclosure is not limited to the embodiments. A person having ordinary knowledge in the art to which the present disclosure pertains may substitute, modify, and change the embodiments in various ways without departing from the technical spirit of the present disclosure written in the claims. Such substitutions, modifications, and changes may be said to belong to the scope of the present disclosure. Furthermore, the embodiments may be combined to form additional embodiments.

What is claimed is:

1. A semiconductor system comprising:
a command address bus;
a data bus;
a management bus;
a memory module including multiple memories and coupled to the command address bus, data bus and management bus;
a memory controller configured to control, through the command address bus and the data bus, the memory module to perform a write operation and a read operation; and
a baseboard management controller configured to perform, through the management bus, a management operation of managing the multiple memories.

2. The semiconductor system of claim 1, wherein the baseboard management controller performs the management operation before the memory controller is powered up.

3. The semiconductor system of claim 1, wherein the baseboard management controller performs the management operation in a situation in which the memory controller is unable to operate.

4. The semiconductor system of claim 1, wherein each of the multiple memories includes a register configured to store therein a state information of the memory.

5. The semiconductor system of claim 4, wherein each of the multiple memories is configured to transmit, to the baseboard management controller through the management bus, the state information stored in the register included therein.

6. The semiconductor system of claim 5, wherein the state information includes one or more pieces of temperature information, error information and word line information.

7. The semiconductor system of claim 6, wherein the baseboard management controller performs the management operation by changing, when receiving the temperature information representing that a temperature of the memory is greater than a preset range, a level of a source voltage supplied to the memory.

8. The semiconductor system of claim 6, wherein the baseboard management controller performs the management operation by determining, based on the error information, whether an error rate of the memory is greater than a preset error rate.

9. The semiconductor system of claim 8, wherein the baseboard management controller performs the management operation by causing, when the error rate is determined as greater than the preset error rate, the memory to perform a repair operation on the memory.

10. The semiconductor system of claim 6, wherein the word line information represents at least a word line accessed a preset number of times or more.

11. The semiconductor system of claim 10, wherein the baseboard management controller performs the management operation by causing, according to the word line information, the memory to perform a refresh operation for neighboring word lines adjacent to the word line.

12. The semiconductor system of claim 1, wherein the management bus operates according to a scheme of memory module management control (M3C) interface.

13. An operating method of a semiconductor system including a controller and multiple memories coupled to the controller through in-band interface and a baseboard management controller coupled to the multiple memories through side-band interfaces, the operating method comprising:
controlling, by the controller, the multiple memories through the in-band interface;
selecting, by the baseboard management controller, one of the multiple memories through the side band interface;
receiving, by the baseboard management controller, information from a register of the selected memory; and
requesting, by the baseboard management controller to the selected memory, a processing operation for fail information when the information includes the fail information.

14. The operating method of claim 13, wherein selecting includes sequentially selecting the multiple memories, one at a time.

15. The operating method of claim 13, wherein the information includes one or more of a first information piece representing a temperature greater than a preset range, a second information piece representing an address indicating a memory area having a greater error rate than a preset error rate, and a third information piece representing a word line that has been accessed a preset number of times or more.

16. The operating method of claim 15, wherein the fail information represents whether or not the information includes one or more of the first to third information pieces.

17. The operating method of claim 16, wherein requesting includes requesting to control a level of a source voltage provided to the selected memory when the fail information represents that the information includes the first information piece.

18. The operating method of claim 16, wherein requesting includes requesting a repair operation for the memory area when the fail information represents that the information includes the second information piece.

19. The operating method of claim 16, wherein requesting includes requesting a refresh operation for neighbouring word lines adjacent to the word line when the fail information represents that the information includes the third information piece.

20. A memory comprising:
a memory cell array configured to perform a read operation or a write operation based on a clock, a command, and an address that are provided through a command/address bus and data that is provided through a data bus;
an error correction circuit configured to correct an error of data output as a result of the read operation of reading the data from a memory area within the memory cell array and to store therein a fail address indicating the memory area at which the error has occurred; and
an alert address processing circuit configured to store therein, when the provided address is identical with the fail address, information provided from the error correction circuit, for determining an error rate of the data.

21. The memory of claim 20, wherein the error correction circuit comprises:
an ECC circuit configured to correct the error to output the error-corrected data, and
a fail address register configured to store therein the fail address.

22. The memory of claim 21,
further comprising a baseboard management controller coupled to the fail address register through a side-band interface,
wherein the fail address register is further configured to transmit the stored fail address to the baseboard management controller.

23. The memory of claim 21,
wherein the ECC circuit is further configured to generate error information representing whether the error is corrected, and
wherein the alert address processing circuit stores the information by:
counting, when the provided address is identical with the fail address, the error information from the ECC circuit, and
storing therein a result of the counting.

24. The memory of claim 23, wherein the alert address processing circuit includes:
a comparator configured to compare the address with the fail address;
a counter configured to count the error information when the provided address is identical with the fail address; and
an alert count register configured to store the result of the counting.

25. The memory of claim 24,
further comprising a baseboard management controller coupled to the fail address register through a side-band interface,
wherein the alert count register is further configured to transmit the stored information to the baseboard management controller.

26. The memory of claim 24,
wherein the error information includes:
fail information indicating that the data has the error, and
pass information indicating that the data does not have the error, and
wherein the counter counts the error information by:
generating a fail count value by counting the fail information,
generating a pass count value by counting the pass information, and
generating a total count value representing a sum of the fail count value and the pass count value whenever the ECC circuit provides the error information.

27. The memory of claim 26, wherein the result of the counting includes the fail count value, the pass count value, and the total count value for the fail address.

28. An operating method of a semiconductor system, the operating method comprising:
performing, through an in-band interface, a read operation of reading data from a memory area;
transmitting, through a side-band interface, information of a fail address indicating the memory area, at which an ECC error has occurred in the data;
determining an error rate based on the information; and
registering the fail address as an alert address when the error rate is greater than a preset error rate.

29. The operating method of claim 28, wherein the information includes fail information and pass information, and count values of the fail information and pass information.

30. The operating method of claim 29,
wherein the fail information indicates that the data has the error, and the pass information indicates that the data does not have the error, and
wherein the count values comprise:
a fail count value of the fail information,
a pass count value of the pass information, and
a total count value representing a sum of the fail count value and the pass count value, the total count value being counted whenever the information is transmitted.

31. The operating method of claim 30, wherein the error rate is determined based on at least one of the pass count value, the fail count value, and the total count value.

32. The operating method of claim 31, further comprising:
comparing whether a subsequently provided address is identical with the alert address, the subsequently provided address for a subsequent read operation performed subsequently to the read operation;
checking, through the side-band interface, the information of the alert address when the subsequently provided address is identical with the alert address; and
performing a repair operation on the memory area when the error information is greater than a threshold.

33. The operating method of claim 32, wherein the information of the alert address is checked based on whether each of the fail count value, the pass count value, and the total count value is greater than the threshold.

34. A memory comprising:
a temperature sensor configured to sense a temperature of the memory;
a temperature register configured to store therein alert temperature information; and
an alert temperature information generation circuit configured to store the alert temperature information in the temperature register when the temperature is greater than a preset range.

35. The memory of claim 34, wherein the memory is operable according to a control of an external controller through an in-band interface.

36. The memory of claim 34, wherein the temperature register is further configured to transmit the stored alert temperature information to an external baseboard management controller through a side-band interface.
